(19) United States
(12) Patent Application Publication
(10) Pub. No.: US 2025/0204059 A1
(43) Pub. Date: Jun. 19, 2025

(54) SEMICONDUCTOR LIGHT-RECEIVING DEVICE AND METHOD FOR MANUFACTURING SAME

(71) Applicant: Mitsubishi Electric Corporation, Tokyo (JP)

(72) Inventors: Harunaka YAMAGUCHI, Tokyo (JP); Eitaro ISHIMURA, Tokyo (JP); Akitsugu NIWA, Tokyo (JP); Ryota TAKEMURA, Tokyo (JP)

(73) Assignee: Mitsubishi Electric Corporation, Tokyo (JP)

(21) Appl. No.: 18/849,222

(22) PCT Filed: Jun. 22, 2022
(86) PCT No.: PCT/JP2022/024800

§ 371 Date: Sep. 20, 2024

(51) Int. Cl. H10F 30/225; H10F 71/00; H10F 77/124

(52) U.S. Cl. CPC H10F 30/2255; H10F 71/1272; H10F 77/1248

(57) ABSTRACT

A semiconductor light-receiving device according to the present disclosure includes: a semiconductor substrate; a multiplication layer formed above the semiconductor substrate; the multiplication layer composed of a digital alloy structure including a first semiconductor layer having a thickness of N times (1≤N≤20) a thickness of a monoatomic layer and a second semiconductor layer having a thickness of M times (1≤M≤20) the thickness of the monoatomic layer with a smaller bandgap energy than the first semiconductor layer in which the first semiconductor layer and the second semiconductor layer are alternately stacked a plurality of times therein; a light absorption layer formed above the multiplication layer; and an electric field relaxation layer formed between the multiplication layer and the light absorption layer; and a strain relaxation layer formed between the multiplication layer and the electric field relaxation layer.

### TECHNICAL FIELD

The present disclosure relates to a semiconductor light-receiving device and a method for manufacturing the same.

### BACKGROUND ART

In recent years, with the development of the information society, the growth of optical communication networks, which are the backbone of the information society, has been remarkable. In particular, with the rapid development of data centers that handle a large amount of data and the development of 5th Generation Mobile Communications Systems, optical communications used for both short-distance and long-distance communications have been remarkably increased in speed and capacity. In optical communications, an avalanche photodiode (APD) having excellent performance is used on a receiving side of communication data.

The APD is mainly used on the receiving side of long-distance transmission because the APD has a function of generating carriers consisting of electron-hole pairs from an optical signal received during data communication and amplifying the carriers themselves. The use of the APD also eliminates the requirement for an external carrier amplifier on the receiving side, which is necessary when ordinary light-receiving devices are used inside the communications apparatus. Consequently, even in the case of the short-distance communications, the APD is used as a light-receiving device.

There are several types of operation principles of the APD. Among them, a separate absorption, charge and multiplication avalanche photodiode (SACM-type APD) structure in which a layer that receives signal light and generates carriers (carrier generation layer) and a layer that multiplies the generated carriers (multiplication layer) are separated is excellent in performance.

In the optical communications, a layer for receiving signal light (light absorption layer) and the multiplication layer for multiplying generated carriers are made of InGaAs and AlInAs, respectively, above an InP substrate, and a layer called an electric field relaxation layer (AlInAs or the like) is inserted between the AlInAs multiplication layer and the InGaAs light absorption layer in order to relax the electric field intensity applied to both layers, thereby achieving the operation as APDs. When light is incident on the APD manufactured with such a configuration, photocarriers consisting of electrons and holes are generated within the InGaAs light absorption layer, and then the electrons are conducted into the AlInAs multiplication layer by reverse biasing. Since the electrons, which are the photocarriers, are multiplied by the avalanche amplification effect within the AlInAs multiplication layer, enabling the optical signal received to be amplified.

The performance of the APD is mainly determined by the noise during carrier multiplication, which depends on the constituent material of the multiplication layer. For example, in the Si-APD disclosed in Non-Patent Document 1, since a germanium (Ge) light absorption layer and a Si multiplication layer on a silicon (Si) substrate are used, and thus the noise of the APD can be reduced as compared with AlInAs, which is a compound semiconductor, used as a constituent material of the multiplication layer.

Non-Patent Document 2 also discloses that the application of a technology called Digital Alloy, which controls a layer thickness at an atomic layer level, to binary compound semiconductors (AlAs, InAs) or ternary compound semiconductors (AlₓIn₁₋ₓAs) that constitute the AlInAs multiplication layer made of compound semiconductors, enables lower noise than that of conventional APDs using AlInAs.

The multiplication layer formed by repeating layers whose layer thicknesses are controlled at the atomic layer level by the digital alloy technique disclosed in Non-Patent Document 2 has a new physical property value different from that of conventional materials by controlling the electron orbit itself of the semiconductor material. This new physical property is different from the quantum effect exhibited by the multiplication layer composed of a superlattice structure as disclosed in Patent Document 1. In particular, it has been reported that the AlInAs multiplication layer composed of the digital alloy structure in which AlAs and InAs are stacked at the atomic layer level enables very low noise during avalanche multiplication operation, as compared to conventional APDs with the multiplication layer made of AlInAs lattice-matched on the InP substrate.

### CITATION LIST

### Patent Document

Patent Document 1: Japanese Patent No. 2671569
Patent Document 2: Specification of U.S. Pat. No. 6,326,650

### Non-Patent Document

Non-Patent Document 1: M. Huang, et al., “Germanium on Silicon Avalanche Photodiode”, IEEE Journal of Selected Topics in Quantum Electronics, Vol. 24, No. 2, 3800911, 2018
Non-Patent Document 2: J. Zheng, et al., “Digital Alloy InAlAs Avalanche Photodiodes”, IEEE Journal of Lightwave Technology, Vol. 36, No. 17, pp. 3580 to 3585, 2018
Non-Patent Document 3: D. C. Houghton, et al., “Comparison of chemical beam epitaxy and metalorganic chemical vapour deposition for highly strained multiple quantum well InGaAsP/InP 1.5 μm lasers”, J. Crystal Growth, Vol. 136, pp. 56 to 63, 1994

### SUMMARY OF THE INVENTION

### Problem to be Solved by the Invention

Patent Document 2 discloses the application of a digital alloy type multiplication layer as a multiplication layer of an APD. However, the APD described in Document 2 does not separate the absorption layer where the photocarriers are generated and the multiplication layer where the carriers are multiplied, resulting in increased noise and reduced receiving sensitivity with such a device structure.

The Si-APD disclosed in Non-Patent Document 1 requires the crystal growth of Ge having a layer thickness of about 1 μm for a light absorption layer on the Si substrate. However, since Ge is lattice-mismatched with the Si substrate, crystal defects are easily generated, thereby making it difficult to grow crystals with a thicker layer thickness. In addition, the dark current tends to increase due to the crystal defects, making it difficult to achieve stable device characteristics for APDs.

In order to improve the performance of APDs on the basis of the compound semiconductors using InP for a semiconductor material constituting APDs, it is preferable to apply the AlInAs multiplication layer composed of the digital alloy structure to SACM-type APDs by using the digital alloy technique disclosed in Non-Patent Document 1. However, since both AlAs and InAs, which constitute the multiplication layer composed of the digital alloy structure, are lattice-mismatched with InP that constitutes the substrate, the crystal quality of the electric field relaxation layer and the light absorption layer grown on the upper surface side of the multiplication layer may be significantly degraded, and thus, as in the Si-APD described above, degradation of the device characteristics as APDs due to an increase in dark current caused by the crystal defects is concerned.

Furthermore, since the AlInAs multiplication layer composed of the digital alloy structure has a bandgap difference from the layer on the upper surface side or the lower surface side of the multiplication layer, when the photocarriers generated upon incidence of light are conducted in the multiplication layer composed of the digital alloy structure in the vertical direction with respect to the substrate surface, the bandgap difference at the interface between the multiplication layer and each of the upper and lower layers may interfere with high-speed operation for APDs.

That is, simply applying the AlInAs multiplication layer composed of the digital alloy structure as the multiplication layer for APDs do not fully demonstrate the excellent characteristics of APDs, such as carrier responsivity.

The present disclosure has been made to solve the above problems, and an object of the present disclosure is to achieve a semiconductor light-receiving device with low noise and high receiving sensitivity, and a method for manufacturing the semiconductor light-receiving device.

### Means to Solve the Problem

A semiconductor light-receiving device according to the present disclosure includes: a semiconductor substrate; a multiplication layer formed above the semiconductor substrate and configured to amplify photocarriers, the multiplication layer being composed of a digital alloy structure including a first semiconductor layer having a thickness of N times (1≤N≤20) a thickness of a monoatomic layer and a second semiconductor layer having a thickness of M times (1≤M≤20) the thickness of the monoatomic layer with a smaller bandgap energy than the first semiconductor layer, the first semiconductor layer and the second semiconductor layer being alternately stacked a plurality of times in the digital alloy structure; a light absorption layer formed on the multiplication layer and configured to absorb incident light to generate the photocarriers; and an electric field relaxation layer formed between the multiplication layer and the light absorption layer.

A method for manufacturing a semiconductor light-receiving device according to the present disclosure includes: a step of sequentially epitaxially growing, on an n-type InP substrate, an n-type AlInAs buffer layer, an AlInAs multiplication layer composed of a digital alloy structure including an AlAs layer having a thickness of N times (1≤N≤20) a thickness of a monoatomic layer and an InAs layer having a thickness of M times (1≤M≤20) the thickness of the monoatomic layer in which the AlAs layer and the InAs layer are alternately stacked a plurality of times, a p-type AlInAs electric field relaxation layer, an n-type InGaAs light absorption layer, an i-type AlInAs window layer, an n-type InP window layer, and a p-type InGaAs contact layer; and a step of forming a Zn selective diffusion region in the n-type InP window layer and a part of the i-type AlInAs window layer.

### Effect of the Invention

According to the semiconductor light-receiving device and the method for manufacturing the semiconductor light-receiving device of the present disclosure, a semiconductor light-receiving device with low noise and high receiving sensitivity can be achieved, and such semiconductor light-receiving device can be easily manufactured.

### BRIEF DESCRIPTION OF THE DRAWINGS

FIG. 1 is a cross-sectional view showing a device structure of a semiconductor light-receiving device according to Embodiment 1;

FIG. 2 is a cross-sectional view showing a device structure of a semiconductor light-receiving device according to Embodiment 2;

FIG. 3 is a diagram for explaining effective stress of a digital alloy structure depending on the presence or absence of a strain relaxation layer in the semiconductor light-receiving device according to Embodiment 2;

FIG. 4 is a cross-sectional view showing a device structure of a semiconductor light-receiving device according to Embodiment 3;

FIG. 5 is a diagram for explaining the relationship between the bandgap energies of the semiconductor light-receiving device according to Embodiment 3, in which FIG. 5A shows a case where the first transition layer is not provided, and FIG. 5B shows a case where the first transition layer is provided;

FIG. 6 is a cross-sectional view showing a device structure of a semiconductor light-receiving device according to Embodiment 4;

FIG. 7 is a diagram for explaining the relationship between the bandgap energies of the semiconductor light-receiving device according to Embodiment 4, in which FIG. 7A shows a case where the second transition layer is not provided, and FIG. 7B shows a case where the second transition layer is provided;

FIG. 8 is a cross-sectional view showing a device structure of a semiconductor light-receiving device according to Embodiment 5;

FIG. 9 is a diagram showing an electric field intensity distribution in a direction perpendicular to a substrate;

FIG. 10 is a diagram for comparing the maximum electric field intensity E_{MAX} in the case where the outermost surface layers of the i-type AlInAs multiplication layer composed of the digital alloy structure are AlAs layers and in the case where the outermost surface layers thereof are InAs layers.

### DESCRIPTION OF EMBODIMENTS

### Embodiment 1

### <Device Structure of Semiconductor Light-Receiving Device 100 According to Embodiment 1>

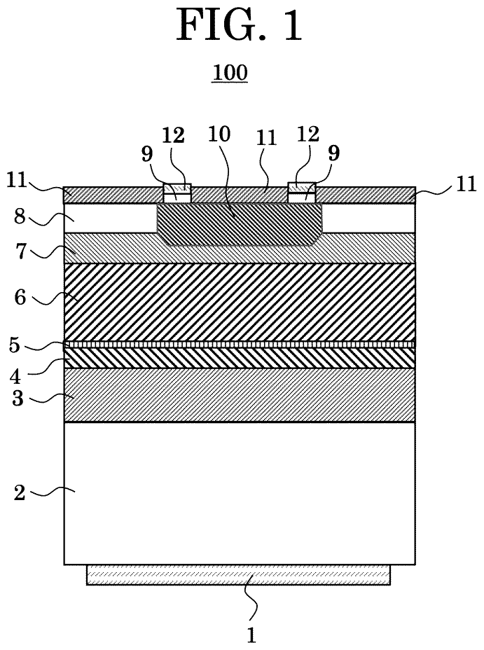

FIG. 1 is a cross-sectional view showing the device structure of a semiconductor light-receiving device 100 according to Embodiment 1. As an example of the semiconductor light-receiving device 100 according to Embodiment 1, a SACM-type APD is given.

The semiconductor light-receiving device 100 according to Embodiment 1 includes: an n-type AlInAs buffer layer 3 having a thickness of 0.1 to 0.5 μm and a doping concentration of 1×10¹⁸ to 5×10¹⁸ cm⁻³; an i-type AlInAs multiplication layer having a thickness of 0.05 to 0.2 μm and composed of a digital alloy structure in which an i-type AlAs layer (for example, layer thickness 2 ML) and an i-type InAs layer (for example, layer thickness 2 ML) are alternately stacked a plurality of times; a p-type AlInAs electric field relaxation layer 5 having a thickness of 0.05 to 0.15 μm and a doping concentration of 5×10¹⁷ to 1×10¹⁸ cm⁻³; an n-type InGaAs light absorption layer 6 having a thickness of 1 to 1.5 μm and a doping concentration of 1×10¹⁵ to 5×10¹⁵ cm⁻³; an i-type AlInAs window layer 7 having a thickness of 0.05 to 1 μm; an n-type InP window layer 8 having a thickness of 0.5 to 1 μm and a doping concentration of 1×10¹⁴ to 5×10¹⁵ cm⁻³; and a p-type InGaAs contact layer 9, with a circular ring shape, having a thickness of 0.1 to 0.5 μm and a doping concentration of 1×10¹⁸ to 5×10¹⁸ cm⁻³, wherein above layers are sequentially formed above an n-type InP substrate 2.

The semiconductor light-receiving device 100 according to Embodiment 1 further includes: a Zn selective diffusion region 10 provided in the n-type InP window layer 8 and a part of the i-type AlInAs window layer 7; a SiNₓ surface protective film 11 provided on the surface of the n-type InP window layer 8 including the surface of the Zn selective diffusion region 10; the n-type electrode 1 provided on the back surface of the n-type InP substrate 2; and a p-type electrode 12 provided on the surface of the p-type InGaAs contact layer 9 with the circular ring shape.

The semiconductor light-receiving device 100 according to Embodiment 1 is characterized in that the i-type AlInAs multiplication layer 4 is composed of the digital alloy structure, and that the p-type AlInAs electric field relaxation layer 5 is provided between the i-type AlInAs multiplication layer 4 and the n-type InGaAs light absorption layer 6. Note that in the description of each embodiment, the composition ratio of AlInAs and InGaAs constituting each layer is not specified except for AlInAs constituting the multiplication layer 4, but both of them preferably have a composition ratio lattice-matched with the n-type InP substrate 2.

In the above description, as an example of the multiplication layer for the SACM-type APD, the i-type AlInAs multiplication layer 4 composed of the digital alloy structure in which the i-type AlAs layer having the thickness of two monatomic layers (ML), that is, the thickness of 2 ML and the i-type InAs layer having the thickness of 2 ML are alternately stacked a plurality of times has been described. The thickness of the i-type AlAs layer may be in the range of N times (1≤N≤20) the thickness of the monoatomic layer, and the thickness of the i-type InAs layer may be in the range of M times (1≤M≤20) the thickness of the monoatomic layer. It is more preferable that the thickness of the i-type AlAs layer is within a range of N times (1≤N≤5) the thickness of the monoatomic layer, and the thickness of the i-type InAs layer is within a range of M times (1≤M≤5) the thickness of the monoatomic layer. In the i-type AlInAs multiplication layer 4 composed of the digital alloy structure, the number of times of stacking when the i-type AlAs layer and the i-type InAs layer are alternately stacked a plurality of times is preferably in a range of 5 times or more and 300 times or less.

In the following description, two kinds of layers of different semiconductor materials constituting the AlInAs multiplication layer composed of the digital alloy structure may be referred to as a first semiconductor layer 4a and a second semiconductor layer 4b. The bandgap energy Eg₁ of the first semiconductor layer 4a is larger than the bandgap energy Eg₂ of the second semiconductor layer 4b. That is, the relationship Eg₁>Eg₂ is satisfied. In the above-described example, the first semiconductor layer 4a is composed of the AlAs layer having the bandgap energy of 2.12 eV, and the second semiconductor layer 4b is composed of the InAs layer having the bandgap energy of 0.36 eV.

### <Method for Manufacturing Semiconductor Light-Receiving Device 100 According to Embodiment 1>

First, a method for manufacturing the SACM-type APD, which is an example of the semiconductor light-receiving device 100 according to Embodiment 1, will be described below.

The n-type AlInAs buffer layer 3, the i-type AlInAs multiplication layer 4 composed of the digital alloy structure in which the i-type AlAs layer (layer thickness 2 ML) and the i-type InAs layer (layer thickness 2 ML) are alternately stacked a plurality of times, the p-type AlInAs electric field relaxation layer 5, the n-type InGaAs light absorption layer 6, the i-type AlInAs window layer 7, the n-type InP window layer 8, and the p-type InGaAs contact layer 9 are sequentially crystal-grown above the n-type InP substrate 2, by an epitaxial crystal growth method such as metal-organic vapor phase epitaxy (MOVPE) or molecular beam epitaxy (MBE).

In the case where the MOVPE method is used as the epitaxial crystal growth method, the crystal growth temperature is preferably about 550° C., but may be in the temperature range of 500° C. to 600° C.

In the wafer process after the epitaxial crystal growth described above, processing, film formation and electrode formation of the device region by reactive ion etching, CVD (Chemical Vapor Deposition), vapor deposition, and the like are performed to form the device structure necessary for functioning as the SACM-type APD.

After the epitaxial crystal growth, a SiOₓ film is deposited on the wafer surface by the CVD method or the like. The SiOₓ film is an insulating film and functions as a diffusion mask.

A circular opening portion is provided in the SiOₓ film by patterning using a circular pattern mask having a diameter of 40 μm by photolithography and etching techniques. The Zn selective diffusion region 10 is formed in the n-type InP window layer 8 and a part of the i-type AlInAs window layer 7 by a method of diffusing zinc (Zn) into the semiconductor layers from the opening portion using the SiOₓ film as the diffusion mask. The tip portion of the Zn selective diffusion region 10 inside the semiconductor layers is located in the i-type AlInAs window layer 7. The Zn selective diffusion region 10 functions as a p-type conductive region. After the Zn selective diffusion region 10 is formed, the SiOₓ film is removed by wet etching or dry etching.

Next, the p-type InGaAs contact layer 9 is processed by reactive ion etching or the like using photolithography and etching techniques such that the p-type InGaAs contact layer 9 remains in a circular ring shape having a width of about 3.0 to 5.0 μm on the Zn selective diffusion region 10.

Thereafter, the SiNₓ surface protective film 11 is formed on the wafer surface by the CVD method or the like. Subsequently, only the SiNₓ surface protective film 11 on the surface of the p-type InGaAs contact layer 9 is removed by photolithography and etching techniques. The SiNₓ surface protective film 11 also functions as an anti-reflection film.

Metal materials such as Ti/Au are deposited on the surface of the p-type InGaAs contact layer 9 by vapor deposition or the like to form the p-type electrode 12.

Finally, the back surface of the n-type InP substrate 2 is ground, and then a film of metal materials such as AuGeNi are formed by the vapor deposition or the like to form the n-type electrode 1. The above is the method for manufacturing the SACM-type APD as an example of the semiconductor light-receiving device 100 according to Embodiment 1.

### <Operation of Semiconductor Light-Receiving Device 100 According to Embodiment 1>

The operation of the SACM-type APD, which is an example of the semiconductor light-receiving device 100 according to Embodiment 1 manufactured by the above-described manufacturing method, will be described below.

First, a reverse bias voltage is applied from the outside and held such that the n-type electrode 1 provided on the back surface side of the n-type InP substrate 2 of the SACM-type APD is positive and the p-type electrode 12 provided on the front surface side is negative. The reverse bias voltage is set to a voltage value at which avalanche amplification sufficiently occurs.

When a reverse bias voltage is applied to the SACM-type APD and light with a wavelength of 1.3 μm or 1.55 μm, which is the wavelength band used in the optical communications, is incident from the p-type electrode 12 side to the Zn selective diffusion region 10, which is the p-type conductive region, the light is absorbed in the n-type InGaAs light absorption layer 6 and thus photocarriers (electron-hole pairs) are generated. With a reverse bias voltage applied to the SACM-type APD, electrons move to the n-type electrode 1 side whereas holes move to the p-type electrode 12 side.

In the SACM-type APD to which the reverse bias voltage is applied, the electric field intensity is controlled by the p-type AlInAs electric field relaxation layer 5 such that avalanche amplification generates when the electrons are conducted into the i-type AlInAs multiplication layer 4 composed of the digital alloy structure. Within the i-type AlInAs multiplication layer 4 composed of the digital alloy structure, the electrons ionize to generate new electron-hole pairs, and then the newly generated electrons and holes together cause ionization, resulting in avalanche amplification of the electrons and the holes, that is, avalanche amplification. That is, since the electrons, which are the photocarriers, are multiplied by an avalanche amplification effect within the i-type AlInAs multiplication layer 4, enabling the optical signal received to be amplified.

### <Operation of Semiconductor Light-Receiving Device According to Embodiment 1>

In the SACM-type APD (semiconductor light-receiving device), which is an electron multiplication type, when the photocarriers generated in the n-type InGaAs light absorption layer are multiplied within the multiplication layer, not only the electrons but also the holes are multiplied, which causes noise during the operation of the APD. The amplitude of noise is denoted by i_{Ns}, the elementary charge of an electron is denoted by q, the average current value flowing through the avalanche region is denoted by I, the bandwidth is denoted by B, the avalanche multiplication factor is denoted by M, and the excess noise factor is denoted by F, the noise component that degrades the receiving sensitivity is expressed by the following Expression (1).

$$[ Mathematical Formula 1 ]$$

$${i}_{Ns}^{2} = 2 {qIBM}^{2} F \qquad ( 1 )$$

The excess noise factor F is expressed by the following Expression (2) using an ionization rate ratio k indicating a multiplication factor ratio of holes and electrons.

$$[ Mathematical Formula 2 ]$$

$$F = M [ 1 - ( 1 - k ) {( \frac{M - 1}{M} )}^{2} ] \qquad ( 2 )$$

The ionization rate ratio k takes a material-specific value. In the case where the ionization rate ratio k is small, the ratio of multiplication of electrons is large, and thus the excess noise factor F is small, and the amplitude of noise i_{Ns} is also small. Consequently, in the S/N ratio during the operation of APDs, the noise component N, which is the denominator, becomes small, and thus APDs with high sensitivity characteristics can be achieved.

Since the ionization rate ratio k takes a material-specific value, semiconductor materials that can be crystal-grown to a required layer thickness while maintaining lattice-matching with the substrate and have an ionization rate ratio k as small as possible are usually selected as semiconductor materials constituting APDs.

In the case where a binary compound semiconductor (AlAs, InAs) or ternary compound semiconductor (AlₓIn₁₋ₓAs) is applied to the semiconductor material constituting the multiplication layer, as disclosed in Non-Patent Document 1, and a multilayer structure formed by the crystal growth at the atomic layer level is used, the value of ionization rate ratio k can be further reduced because the electron multiplication factor can be improved or the hole multiplication can be suppressed compared to ordinary semiconductor materials.

As described above, for example, AlInAs in which binary compound semiconductor materials such as AlAs and InAs are stacked at the atomic layer thickness level is applied as a semiconductor material constituting the multiplication layer composed of the digital alloy structure of the APD, and the electric field intensity applied to the multiplication layer is controlled to be larger than the electric field applied to the light absorption layer by the electric field relaxation layer, as the SACM-type APD. Thus, the SACM-type APD with low noise and high receiving sensitivity can be achieved.

In Embodiment 1, the case where AlInAs is used as an example of the semiconductor material constituting the multiplication layer of the SACM-type APD has been described. As the semiconductor material constituting the multiplication layer, for example, even when semiconductor materials capable of the crystal growth by combining a group III material and a group V material such as InGaAsP, AlGaInAs, AlAsSb, AlGaAsSb, AlInAsSb, and AlGaInaSb are stacked at the atomic layer level as binary, ternary or quaternary compound semiconductor materials (InP, AlAs, InGaAs, AlInAs, GaAsSb, AlGaInAs, AlGaAsSb, and the like) constituted therein, the same improvement effect can be achieved as the device characteristics of the SACM-type APD.

In the above-described example, the stacked structure of the 2 ML unit is exemplified as the thickness of each layer constituting the digital alloy structure. But the combination of the semiconductor materials is not limited to the above example, and any combination of the semiconductor materials may be used as long as the stacked structure constituting the multiplication layer can be crystal-grown to a critical layer thickness, for example, a layer thickness up to 5 nm, at which the crystal can be grown without causing crystal defects with respect to the underlying n-type InP substrate 2. The i-type AlInAs multiplication layer 4 is undoped, but the multiplication layer is not limited to an undoped layer. That is, the digital alloy structure constituting the multiplication layer may be doped with an n-type or a p-type impurity.

In the above description, the case where the p-type conductive region is formed by Zn diffusion is taken as an example. However, atoms that impart p-type conductivity to the n-type InP window layer 8 and i-type AlInAs window layer 7 may be used as p-type dopants, such as cadmium (Cd) and beryllium (Be), which can be p-type impurities in addition to Zn. The method of Zn diffusion may be a solid phase diffusion method using zinc oxide (ZnO) or a Zn vapor phase diffusion method using a crystal growth furnace, or the p-type contact layer may be crystal-grown by the crystal growth method.

In the above description, a front-surface-incident type structure in which light to be detected is incident from the p-type electrode 12 side to the Zn selective diffusion region 10, which is a p-type conductive region, is given as an example as a SACM-type APD. But the present disclosure is not limited to the front-surface-incident type structure, and the same effect as the SACM-type APD can be expected even in a back-surface-incident type structure in which the n-type electrode 1 is opened in a circular pattern and light is incident from the back surface side of the n-type InP substrate 2, or an edge-incident type structure in which light is incident from an edge surface of the n-type light absorption layer 6.

### Effects of Embodiment 1

As described above, according to the semiconductor light-receiving device and the method for manufacturing the semiconductor light-receiving device of Embodiment 1, the multiplication layer is composed of the digital alloy structure and the electric field relaxation layer is provided between the multiplication layer and the light absorption layer, thus providing an effect that it is possible to stably obtain a semiconductor light-receiving device with low noise and high receiving sensitivity.

### Embodiment 2

### <Device Structure of Semiconductor Light-Receiving Device 110 According to Embodiment 2>

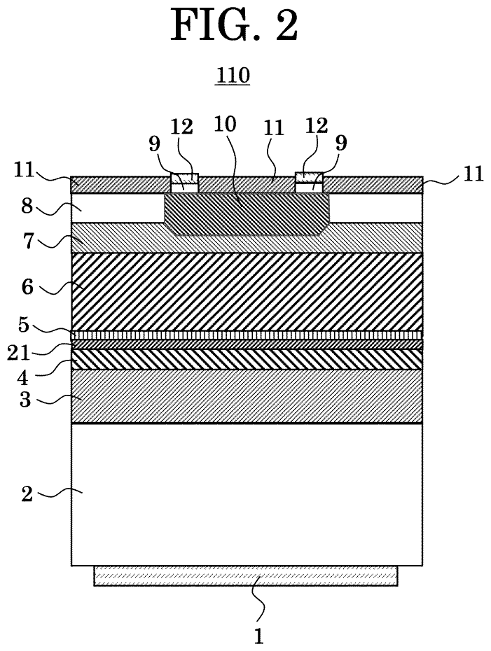

FIG. 2 is a cross-sectional view showing the device structure of a semiconductor light-receiving device 110 according to Embodiment 2. As an example of the semiconductor light-receiving device 110 according to Embodiment 2, a SACM-type APD is given.

The semiconductor light-receiving device 110 according to Embodiment 2 includes: an n-type AlInAs buffer layer 3 having a thickness of 0.1 to 0.5 μm and a doping concentration of 1×10¹⁸ to 5×10¹⁸ cm⁻³; an i-type AlInAs multiplication layer having a thickness of 0.05 to 0.2 μm and composed of a digital alloy structure in which an i-type AlAs layer (for example, layer thickness 2 ML) and an i-type InAs layer (for example, layer thickness 2 ML) are alternately stacked a plurality of times; an i-type AlInAs strain relaxation layer 21 having a thickness of 10 to 100 nm; a p-type AlInAs electric field relaxation layer 5 having a thickness of 0.05 to 0.15 μm and a doping concentration of 5×10¹⁷ to 1×10¹⁸ cm⁻³; an n-type InGaAs light absorption layer 6 having a thickness of 1 to 1.5 μm and a doping concentration of 1×10¹⁵ to 5×10¹⁵ cm⁻³; an i-type AlInAs window layer 7 having a thickness of 0.05 to 1 μm; an n-type InP window layer 8 having a thickness of 0.5 to 1 μm and a doping concentration of 1×10¹⁴ to 5×10¹⁵ cm⁻³; and a p-type InGaAs contact layer 9, with a circular ring shape, having a thickness of 0.1 to 0.5 μm and a doping concentration of 1×10¹⁸ to 5×10¹⁸ cm⁻³, wherein above layers are sequentially formed above an n-type InP substrate 2.

The semiconductor light-receiving device 100 according to Embodiment 2 further includes: a Zn selective diffusion region 10 provided in the n-type InP window layer 8 and a part of the i-type AlInAs window layer 7; a SiNₓ surface protective film 11 provided on the surface of the n-type InP window layer 8 including the surface of the Zn selective diffusion region 10; the n-type electrode 1 provided on the back surface of the n-type InP substrate 2; and a p-type electrode 12 provided on the surface of the p-type InGaAs contact layer 9 with the circular ring shape.

The semiconductor light-receiving device 110 according to Embodiment 2 is characterized in that the i-type AlInAs multiplication layer 4 is composed of the digital alloy structure, and that the i-type AlInAs strain relaxation layer 21 is provided between the i-type AlInAs multiplication layer 4 and the p-type AlInAs electric field relaxation layer 5.

The method for manufacturing the semiconductor light-receiving device 110 according to Embodiment 2 is different from Embodiment 1 only in that the i-type AlInAs strain relaxation layer 21 is further crystal-grown between the i-type AlInAs multiplication layer 4 and the p-type AlInAs electric field relaxation layer 5 during the epitaxial crystal growth, and thus the detailed description of the manufacturing method will be omitted.

### <Operation of Semiconductor Light-Receiving Device 110 According to Embodiment 2>

In the device structure of the APD, it is necessary to crystal-grow a stacked structure having a thickness of about 2 μm on the upper surface side of the multiplication layer, from the electric field relaxation layer to the p-type contact layer positioned on the outermost surface as the semiconductor layer. In particular, during APD operation, the dark current in the multiplication layer and the light absorption layer, which correspond to the active layer portion, increases as the crystal quality deteriorates, and thus the noise caused by the dark current also increases. Consequently, the receiving sensitivity characteristic of the APD is deteriorated, as well as reliability issues. Therefore, in order to prevent the generation of crystal defects in the vicinity of the multiplication layer, it is important to reduce the stress, that is, the strain of the stacked structure itself as much as possible in order to achieve a high-performance and high-reliability APD.

The multiplication layer composed of the digital alloy structure is stacked with alternating compressive and tensile strains as a result of stacking binary or ternary compound semiconductor materials whose lattice constants are mismatched with the lattice constant of the substrate. In such a case, the effective stress τ at the time of generating of dislocation can be calculated by the dynamic equilibrium model disclosed in Non-Patent Document 3. That is, as disclosed in FIG. 2 of Non-Patent Document 3, by configuring the stacking structure such that the effective stress τ is less than or equal to zero and controlling the materials, layer thicknesses, and sequence of the crystal growth of the device structure including the digital alloy structure, it is possible to achieve high-quality crystal growth without generating dislocations, that is, without generating crystal defects, and thus APDs with excellent device characteristics can be achieved.

According to Non-Patent Document 3, the effective stress τ in a structure in which compressive strain and tensile strain are alternately and repeatedly stacked, such as a multiple quantum well structure, is expressed by the following Expression (3) and each parameter.

$$[ Mathematical Formula 3 ]$$

$$τ = A \{ μ \frac{Nhx + ( N - 1 ) Hy}{L} - \frac{B}{L} [ ln ( \frac{β}{b} ) ( L + z ) + ln ( \frac{β}{b} ) z + 2 ln ( \frac{L}{L + z} ) ] \} \qquad ( 3 )$$

$$A = 2 cos ψ cos λ \frac{1 + v}{1 - v} ,$$

$$B = \frac{{μ}_{x} {μ}_{y}}{{μ}_{x} + {μ}_{y}} \frac{b ( 1 - v {cos}^{2} θ )}{4 π ( 1 + v ) cos λ}$$

Ψ: angle formed by interface and slip surface
λ: angle formed by dislocation line and Burger spectrum
ν: Poisson's ratio
μₓ: shear coefficient of compressive strain layer
μ_{y}: shear coefficient of tensile strain layer
μ_{xy}: average shear coefficient of repeatedly stacked portion
b: Burger spectrum
cos θ: angle formed by dislocation line and Burger spectrum
β: core parameter
x: strain amount of compressive strain layer
h: thickness of compressive strain layer
y: strain amount of tensile strain layer
H: thickness of tensile strain layer
Z: thickness of strain relaxation layer
N: number of layers of compressive strain layer
L: calculated value of Nh+(N−1)H

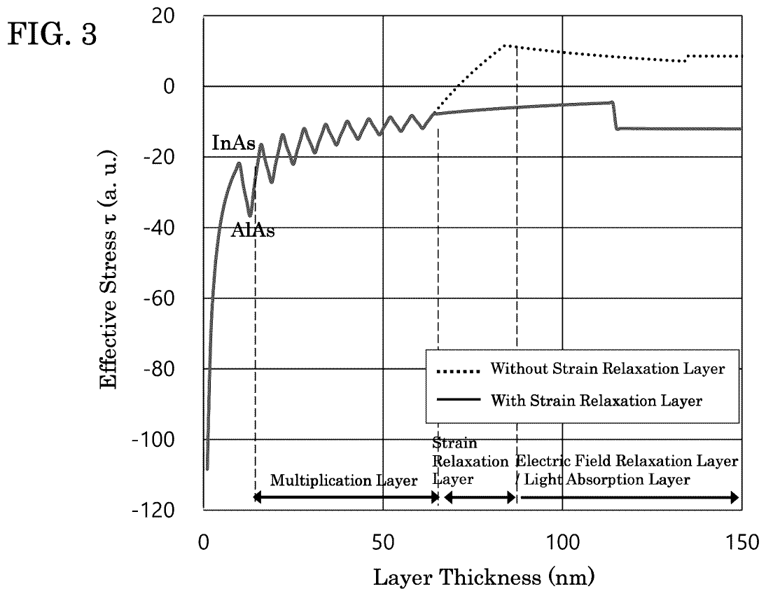

FIG. 3 shows the results of calculation of the effective stress value on the basis of the Expression (3) in both cases of the presence and absence of the strain relaxation layer having a thickness of 50 nm positioned on the upper surface side of the AlInAs multiplication layer composed of the digital alloy structure having a thickness of 50 nm in which the compressive strain layer is formed of the InAs layer and the tensile strain layer is formed of the AlAs layer on the InP substrate. The calculation parameters are referred to Non-Patent Document 3. The InAs and AlAs layers that constitute the digital alloy structure in Embodiment 2 are used as the compressive and tensile strain layers, respectively, and the physical properties of the respective compound semiconductor materials are used.

Because of the high compressive strain of the InAs layer, the effective stress τ on the entire device structure is significantly increased when the AlInAs multiplication layer composed of the digital alloy structure is crystal-grown. In contrast, the AlAs layer, which is crystal-grown immediately after the InAs layer, acts as a tensile strain that operates in the opposite direction to the compressive strain, and thus relaxes the effective stress T. However, the effective stress τ applied to the entire device structure gradually increases as the InAs layer and the AlAs layer are alternately stacked.

When the electric field relaxation layer and the light absorption layer corresponding to the active layer portion of the SACM-type APD is crystal-grown, the stress accumulated in the formation of the AlInAs multiplication layer composed of the digital alloy structure is retained. The calculation results show that without applying the strain relaxation layer, the effective stress τ is above zero when performing the crystal growth of the device structure that requires a thickness of about 2 μm, and thus dislocations are likely to occur, resulting in poor crystal quality.

In contrast, in the case where a strain relaxation layer such as the i-type AlInAs strain relaxation layer 21 is inserted between the i-type AlInAs multiplication layer 4 and the p-type AlInAs electric field relaxation layer 5, as in the SACM-type APD, which is an example of the semiconductor light-receiving device 110 according to Embodiment 2, the effect of strain relaxation by the strain-relaxation layer during the crystal growth of the strain relaxation layer and the light absorption layer enables the effective stress T, which is increased during the crystal growth of the i-type AlInAs multiplication layer 4 consisting of the digital alloy structure, to be reduced. Namely, the insertion of the strain relaxation layer enables the manufacture of the SACM-type APD formed of high-quality semiconductor crystal-growth layers in which no dislocation generates during the crystal growth of the entire device structure.

In Embodiment 2, the i-type AlInAs layer is used as an example of the strain relaxation layer. But the semiconductor material is not limited to AlInAs as long as the semiconductor material lattice-matches the substrate to be used. The strain relaxation layer may be doped with an impurity so as to have a p-type or n-type conductivity, for example, instead of being undoped as described above.

In the case where the effective stress τ can be controlled so as not to exceed zero in the entire device structure, there is no problem even if the strain is applied to the strain relaxation layer itself. Even if the strain relaxation layer itself is strained, a more excellent effect can be achieved by controlling the strain of the entire device structure to be opposite to the average strain of the digital alloy structure.

### Effects of Embodiment 2

As described above, according to the semiconductor light-receiving device of Embodiment 2, since the AlInAs strain relaxation layer is provided between the AlInAs multiplication layer and the AlInAs electric field relaxation layer, the stress generated by the formation of the i-type AlInAs multiplication layer composed of the digital alloy structure can be relaxed, thus providing an effect of achieving a semiconductor light-receiving device with low performance and high receiving sensitivity.

### Embodiment 3

### <Device Structure of Semiconductor Light-Receiving Device 120 According to Embodiment 3>

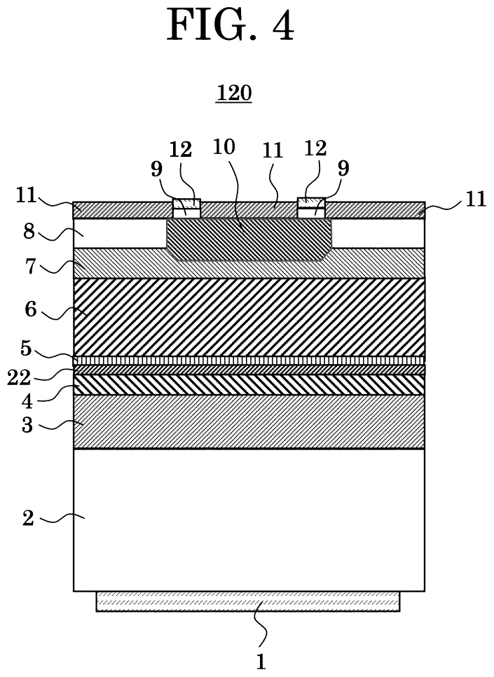

FIG. 4 is a cross-sectional view showing the device structure of a semiconductor light-receiving device 120 according to Embodiment 3. As an example of the semiconductor light-receiving device 120 according to Embodiment 3, a SACM-type is given.

The semiconductor light-receiving device 120 according to Embodiment 3 includes: an n-type AlInAs buffer layer 3 having a thickness of 0.1 to 0.5 μm and a doping concentration of 1×10¹⁸ to 5×10¹⁸ cm⁻³; an i-type AlInAs multiplication layer having a thickness of 0.05 to 0.2 μm and composed of a digital alloy structure in which an i-type AlAs layer (for example, layer thickness 2 ML) and an i-type InAs layer (for example, layer thickness 2 ML) are alternately stacked a plurality of times; an i-type AlₓGa_{y}In_{1-x-y}As (x=0.25, y=0.218) first transition layer 22 having a thickness of 15 nm; a p-type AlInAs electric field relaxation layer 5 having a thickness of 0.05 to 0.15 μm and a doping concentration of 5×10¹⁷ to 1×10¹⁸ cm⁻³; an n-type InGaAs light absorption layer 6 having a thickness of 1 to 1.5 μm and a doping concentration of 1×10¹⁵ to 5×10¹⁵ cm⁻³; an i-type AlInAs window layer 7 having a thickness of 0.05 to 1 μm; an n-type InP window layer 8 having a thickness of 0.5 to 1 μm and a doping concentration of 1×10¹⁴ to 5×10¹⁵ cm⁻³; and a p-type InGaAs contact layer 9, with a circular ring shape, having a thickness of 0.1 to 0.5 μm and a doping concentration of 1×10¹⁸ to 5×10¹⁸ cm⁻³, wherein above layers are sequentially formed above an n-type InP substrate 2.

The semiconductor light-receiving device 120 according to Embodiment 3 further includes: a Zn selective diffusion region 10 provided in the n-type InP window layer 8 and a part of the i-type AlInAs window layer 7; a SiNₓ surface protective film 11 provided on the surface of the n-type InP window layer 8 including the surface of the Zn selective diffusion region 10; the n-type electrode 1 provided on the back surface of the n-type InP substrate 2; and a p-type electrode 12 provided on the surface of the p-type InGaAs contact layer 9 with the circular ring shape.

The semiconductor light-receiving device 120 according to Embodiment 3 is characterized in that the i-type AlInAs multiplication layer 4 is composed of the digital alloy structure, and that the i-type AlₓGa_{y}In_{1-x-y}A first transition layer 22 having the thickness of nm is provided between the i-type AlInAs multiplication layer 4 and the p-type AlInAs electric field relaxation layer 5.

The method for manufacturing the semiconductor light-receiving device 120 according to Embodiment 3 is different from Embodiment 1 only in that the i-type AlₓGa_{y}In_{1-x-y}A first transition layer 22 is further crystal-grown between the i-type AlInAs multiplication layer 4 and the p-type AlInAs electric field relaxation layer 5 during the epitaxial crystal growth, and thus the detailed description of the manufacturing method will be omitted.

### <Operation of Semiconductor Light-Receiving Device 120 According to Embodiment 3>

Photocarriers, which are electrons and holes, generated by light incident on the APD move in a direction opposite to the polarity of the photocarriers in the light absorption layer to which a reverse bias is applied. The electrons generated in the light absorption layer are conducted toward the multiplication layer, pass through the electric field relaxation layer, and then reach the multiplication layer, and an avalanche amplification action occurs within the multiplication layer. In the case of applying the multiplication layer 4 composed of the digital alloy structure, depending on the semiconductor materials combined as the first semiconductor layer 4a and the second semiconductor layer 4b that constitute the digital alloy structure, the band structure of the multiplication layer itself changes and thus the conduction band position thereof becomes higher than the electric field relaxation layer 5. This may result in an electron barrier ΔEc when the electrons are conducted to the multiplication layer 4 composed of the digital alloy structure.

In such a state, in order for the electrons to reach the multiplication layer 4 composed of the digital alloy structure, energy for exceeding the electron barrier ΔEc is required. In particular, during a high-speed response under a low driving voltage, the electron barrier ΔEc may be a barrier to the movement of the electrons. As shown in FIG. 4, the i-type AlₓGa_{y}In_{1-x-y}As (x=0.25, y=0.218) first transition layer 22 with a thickness of 15 nm, is inserted between the multiplication layer 4 and the electric field relaxation layer 5. Here, the i-type first transition layer 22 is composed of, for example, a compound semiconductor material with a bandgap energy Egₘ between a bandgap energy Eg of the multiplication layer 4 composed of the digital alloy structure and a bandgap energy Eg_{b} of the electric field relaxation layer 5. The i-type first transition layer 22 enables to reduce the electron barrier ΔEc when the electrons are conducted to the multiplication layer 4 composed of the digital alloy structure, thus enabling a high-speed response SACM-type APD.

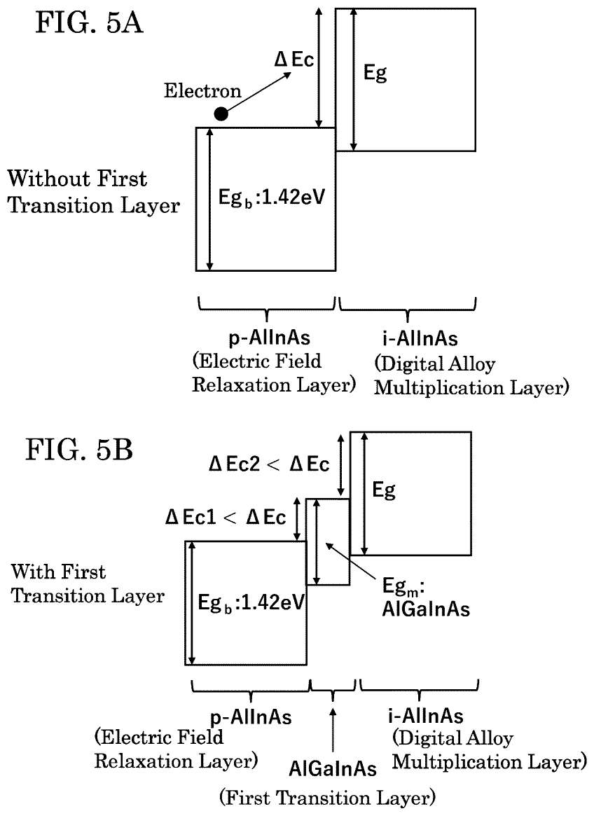

FIG. 5 is a diagram for explaining the relationship between the bandgap energies of the respective layers of the semiconductor light-receiving device 120 according to Embodiment 3. FIG. 5A shows a case where the first transition layer 22 is not provided, and FIG. 5B shows a case where the first transition layer 22 is provided. As shown in FIG. 5A, in the case where the electric field relaxation layer 5 and the multiplication layer 4 composed of the digital alloy structure are in contact with each other, the electrons need to exceed the electron barrier ΔEc to move from the electric field relaxation layer 5 to the multiplication layer 4 composed of the digital alloy structure.

In contrast, as shown in FIG. 5B, in the case where the first transition layer 22 is provided between the electric field relaxation layer 5 and the multiplication layer 4 composed of the digital alloy structure, in order for the electrons to move from the electric field relaxation layer 5 to the first transition layer 22, the electrons need only to exceed the electron barrier ΔEc1, which is smaller than the electron barrier ΔEc. In addition, in order for the electrons to move from the first transition layer 22 to the multiplication layer 4 composed of the digital alloy structure, the electrons need only to exceed the electron barrier ΔEc2 smaller than the electron barrier ΔEc. As described above, it is understood that the effective electron barrier is reduced by providing the first transition layer 22 between the electric field relaxation layer 5 and the multiplication layer 4 composed of the digital alloy structure.

That is, the semiconductor light-receiving device 120 according to Embodiment 3 includes the first transition layer 22, which is formed between the multiplication layer 4 composed of the digital alloy structure and the electric field relaxation layer 5, has the bandgap energy Egₘ between the bandgap energy Eg of the multiplication layer 4 composed of the digital alloy structure and the bandgap energy Eg_{b} of the electric field relaxation layer 5, and thus relaxes the strain of the multiplication layer 4 composed of the digital alloy structure.

In the semiconductor light-receiving device 120 according to Embodiment 3, the i-type AlₓGa_{y}In_{1-x-y}As layer is used as an example of the first transition layer 22. But the AlₓGa_{y}In_{1-x-y}As layer is not limited to the above example, and other semiconductor materials may be used as long as the semiconductor materials have a bandgap energy between the bandgap energy Eg of the multiplication layer 4 composed of the digital alloy structure and the bandgap energy Eg_{b} of the electric field relaxation layer 5. Furthermore, in the case where the first transition layer 22 is formed by combining semiconductor layers having the same composition as the layers constituting the digital alloy structure, the control is facilitated. That is, as in the above-described example, in the case where the digital alloy structure is formed of Al, In, and As, the first transition layer 22 may be formed of Al, In, and As, and thus, the control during the crystal growth is facilitated. Note that, the first transition layer 22 may be doped with an impurity so as to have a conductivity type of, for example, a p-type or an n-type, instead of being undoped.

### Effects of Embodiment 3

As described above, according to the semiconductor light-receiving device of Embodiment 3, since the i-type AlₓGa_{y}In_{1-x-y}As first transition layer is provided between the i-type AlInAs multiplication layer and the p-type AlInAs electric field relaxation layer, the electron barrier between the i-type AlInAs multiplication layer composed of the digital alloy structure and the electric field relaxation layer is effectively reduced, thereby improving the conductivity of carriers, thus providing an effect of achieving a semiconductor light-receiving device capable of high-speed operation.

### Embodiment 4

### <Device Structure of Semiconductor Light-Receiving Device 130 According to Embodiment 4>

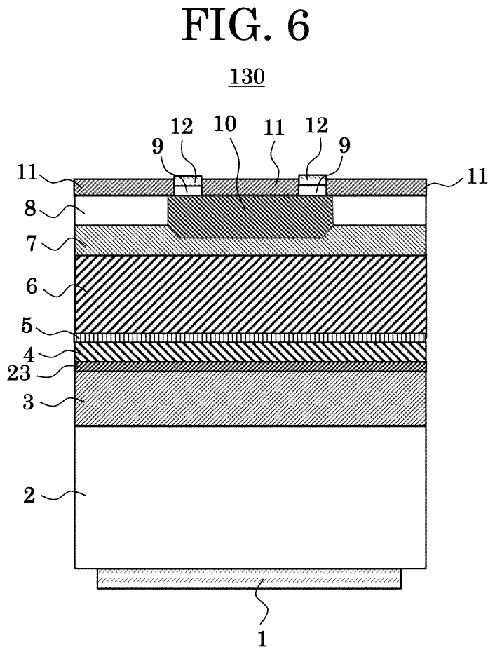

FIG. 6 is a cross-sectional view showing the device structure of a semiconductor light-receiving device 130 according to Embodiment 4. As an example of the semiconductor light-receiving device 130 according to Embodiment 3, a SACM-type APD is given.

The semiconductor light-receiving device 130 according to Embodiment 4 includes: an n-type AlInAs buffer layer 3 having a thickness of 0.1 to 0.5 μm and a doping concentration of 1×10¹⁸ to 5×10¹⁸ cm⁻³; an i-type AlₓGa_{y}In_{1-x-y}As (x=0.25, y=0.218) second transition layer 23 having a thickness of 15 nm; an i-type AlInAs multiplication layer having a thickness of 0.05 to 0.2 μm and composed of a digital alloy structure in which an i-type AlAs layer (for example, layer thickness 2 ML) and an i-type InAs layer (for example, layer thickness 2 ML) are alternately stacked a plurality of times; a p-type AlInAs electric field relaxation layer 5 having a thickness of 0.05 to 0.15 μm and a doping concentration of 5×10¹⁷ to 1×10¹⁸ cm⁻³; an n-type InGaAs light absorption layer 6 having a thickness of 1 to 1.5 μm and a doping concentration of 1×10¹⁵ to 5×10¹⁵ cm⁻³; an i-type AlInAs window layer 7 having a thickness of 0.05 to 1 μm; an n-type InP window layer 8 having a thickness of 0.5 to 1 μm and a doping concentration of 1×10¹⁴ to 5×10¹⁵ cm⁻³; and a p-type InGaAs contact layer 9, with a circular ring shape, having a thickness of 0.1 to 0.5 μm and a doping concentration of 1×10¹⁸ to 5×10¹⁸ cm⁻³, wherein above layers are sequentially formed above an n-type InP substrate 2.

The semiconductor light-receiving device 130 according to Embodiment 4 further includes: a Zn selective diffusion region 10 provided in the n-type InP window layer 8 and a part of the i-type AlInAs window layer 7; a SiNₓ surface protective film 11 provided on the surface of the n-type InP window layer 8 including the surface of the Zn selective diffusion region 10; the n-type electrode 1 provided on the back surface of the n-type InP substrate 2; and a p-type electrode 12 provided on the surface of the p-type InGaAs contact layer 9 with the circular ring shape.

The semiconductor light-receiving device 130 according to Embodiment 4 is characterized in that the i-type AlInAs multiplication layer 4 is composed of the digital alloy structure, and that the i-type AlₓGa_{y}In_{1-x-y}A second transition layer 23 having the thickness of 15 nm is provided between the n-type AlInAs buffer layer 3 and the i-type AlInAs multiplication layer 4.

The method for manufacturing the semiconductor light-receiving device 130 according to Embodiment 4 is different from Embodiment 1 only in that the i-type AlₓGa_{y}In_{1-x-y}A second transition layer 23 is further crystal-grown between the n-type AlInAs buffer layer 3 and the i-type AlInAs multiplication layer 4 during the epitaxial crystal growth, and thus the detailed description of the manufacturing method will be omitted.

### <Operation of Semiconductor Light-Receiving Device 130 According to Embodiment 4>

In the semiconductor light-receiving device 120 according to Embodiment 3, the effect of improving the electron barrier ΔEc is shown when light is incident on the APD and the electrons, which are the photocarriers, generated in the light absorption layer pass through the electric field relaxation layer and reach the multiplication layer. However, the band structure of the i-type AlInAs multiplication layer 4 composed of the digital alloy structure has a lower conduction band position than the n-type AlInAs buffer layer 3 on the substrate side or the electric field relaxation layer 5, which may be a barrier for the electrons.

In such a state, energy for exceeding the electron barrier between the n-type AlInAs buffer layer 3 and the n-type InP substrate 2 is required until the electrons amplified in the i-type AlInAs multiplication layer 4 composed of the digital alloy structure are conducted as carriers to the p-type InGaAs contact layer 9, which may be a barrier to the high-speed operation of the SACM-type APD particularly under a low voltage.

As shown in FIG. 6, in the SACM-type APD which is an example of the semiconductor light-receiving device 130 according to Embodiment 4, the i-type AlₓGa_{y}In_{1-x-y}As (x=0.25, y=0.218) second transition layer 23 with the thickness of 15 nm is inserted between the multiplication layer 4 composed of the digital alloy structure and the n-type buffer layer 3. Here, the i-type second transition layer 23 is composed of, for example, a compound semiconductor material with a bandgap energy Egₙ between a bandgap energy Eg of the i-type AlInAs multiplication layer 4 and a bandgap energy Egₛ of the n-type buffer layer 3, which means the relationship Eg>Egₙ>Egₛ. The i-type second transition layer 23 enables to reduce the electron barrier ΔEc when the electrons passing through the i-type AlInAs multiplication layer 4 are conducted to the p-type InGaAs contact layer 9, thus enabling high-speed response of the SACM-type APD.

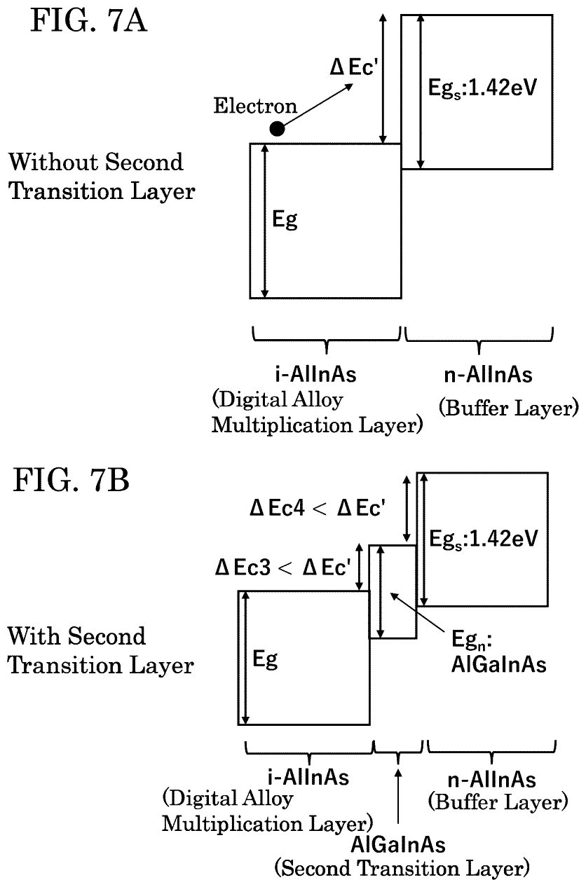

FIG. 7 is a diagram for explaining the relationship between the bandgap energies of the respective layers in the semiconductor light-receiving device according to Embodiment 4. FIG. 7A shows a case where the second transition layer 23 is not provided, and FIG. 7B shows a case where the second transition layer 23 is provided. As shown in FIG. 7A, in the case where the multiplication layer 4 composed of the digital alloy structure and the buffer layer 3 are in contact with each other, the electrons need to exceed an electron barrier ΔEc′ to move from the multiplication layer 4 composed of the digital alloy structure to the buffer layer 3.

In contrast, as shown in FIG. 7B, in the case where the second transition layer 23 is provided between the multiplication layer 4 composed of the digital alloy structure and the buffer layer 3, in order for the electrons to move from the multiplication layer 4 composed of the digital alloy structure to the second transition layer 23, the electrons need only to exceed an electron barrier ΔEc3 smaller than the electron barrier ΔEc′. In addition, in order for the electrons to move from the second transition layer 23 to the buffer layer 3, the electrons need only to exceed an electron barrier ΔEc4 smaller than the electron barrier ΔEc′. As described above, it is understood that the effective electron barrier is reduced by providing the second transition layer 23 between the multiplication layer 4 composed of the digital alloy structure and the buffer layer 3.

Furthermore, the insertion of the i-type AlₓGa_{y}In_{1-x-y}As second transition layer 23 described above also provides an effect of reducing the stress accumulated in the i-type AlInAs multiplication layer 4 composed of the digital alloy structure.

In Embodiment 4, the i-type AlₓGa_{y}In_{1-x-y}As layer is used as an example of the second transition layer 23. Any semiconductor material can be similarly applied to the second transition layer 23 as long as the semiconductor material satisfies the relationship of Eg>Egₙ>Egₛ among the bandgap energy Egₙ of the second transition layer 23, the bandgap energy Eg of the i-type AlInAs multiplication layer 4, and the bandgap energy Egₛ of the n-type AlInAs buffer layer 3. In the case where the second transition layer 23 is formed by combining layers having the same composition as the layers constituting the digital alloy structure, the control is facilitated. Furthermore, the second transition layer 23 may be doped with an impurity so as to have a conductivity type of, for example, a p-type or an n-type, instead of being undoped as shown in the example.

### Effects of Embodiment 4

As described above, according to the semiconductor light-receiving device of Embodiment 4, since the second transition layer is provided between the multiplication layer composed of the digital alloy structure and the n-type buffer layer, the electron barrier generated between the multiplication layer composed of the digital alloy structure and the n-type buffer layer is reduced, thereby improving the carrier conductivity, thus providing an effect of achieving a semiconductor light-receiving device capable of high-speed operation.

### Embodiment 5

### <Device Structure of Semiconductor Light-Receiving Device 140 According to Embodiment 5>

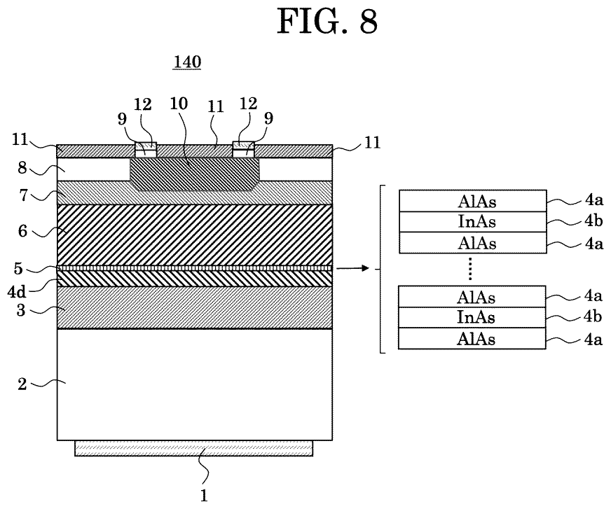

FIG. 8 is a cross-sectional view showing the device structure of the semiconductor light-receiving device 140 according to Embodiment 5. As an example of the semiconductor light-receiving device 140 according to Embodiment 1, a SACM-type APD is given.

The structure of each layer of the semiconductor light-receiving device 140 according to Embodiment 5 is basically the same as the structure of each layer of the semiconductor light-receiving device 100 according to Embodiment 1, but the detailed structure of the i-type AlInAs multiplication layer 4d composed of the digital alloy structure is different. Consequently, only the configuration of the i-type AlInAs multiplication layer 4d composed of the digital alloy structure will be described below.

The i-type AlInAs multiplication layer 4d composed of the digital alloy structure has a thickness of 0.05 to 0.2 μm and is formed by alternately stacking an i-type AlAs layer (for example, layer thickness 2 ML) and an i-type InAs layer (for example, layer thickness 2 ML) a plurality of times. As shown in FIG. 8, the i-type AlAs layer is the last layer stacked as the i-type AlInAs multiplication layer 4d composed of the digital alloy structure, that is, the outermost surface layer. The reason why such a configuration is applied is that, with respect to the i-type AlAs layer and the i-type InAs layer which are two kinds of layers constituting the i-type AlInAs multiplication layer 4d composed of the digital alloy structure, the i-type AlAs layer having a larger bandgap energy of the two kinds of layers is set as the outermost surface layer.

A more general description is given below.

It is assumed that two kinds of layers made of different semiconductor materials, which constitute the i-type AlInAs multiplication layer 4d composed of the digital alloy structure, are a first semiconductor layer 4a and a second semiconductor layer 4b. Here, the bandgap energy Eg₁ of the first semiconductor layer 4a is larger than the bandgap energy Eg₂ of the second semiconductor layer 4b, that is, Eg₁>Eg₂. In the above-described example, the first semiconductor layer 4a is the AlAs layer having the bandgap energy Eg₁ of 2.12 eV, and the second semiconductor layer 4b is the InAs layer having the bandgap energy Eg₂ of 0.36 eV.

The i-type AlInAs multiplication layer 4d composed of the digital alloy structure has the thickness of 0.05 to 0.2 μm, and is formed by alternately stacking the first semiconductor layer 4a and the second semiconductor layer 4b a plurality of times. The first semiconductor layer 4a is the layer that is finally stacked as the i-type AlInAs multiplication layer 4d composed of the digital alloy structure, that is, the outermost surface layer. Namely, the first semiconductor layer 4a is the layer opposite to the p-type AlInAs electric field relaxation layer 5 in the i-type AlInAs multiplication layer 4d composed of the digital alloy structure.

The method for manufacturing the semiconductor light-receiving device 140 according to Embodiment 5 is almost the same as the method for manufacturing the semiconductor light-receiving device 100 according to Embodiment 1, and thus detailed description of the manufacturing method will be omitted.

### Operation of Embodiment 5

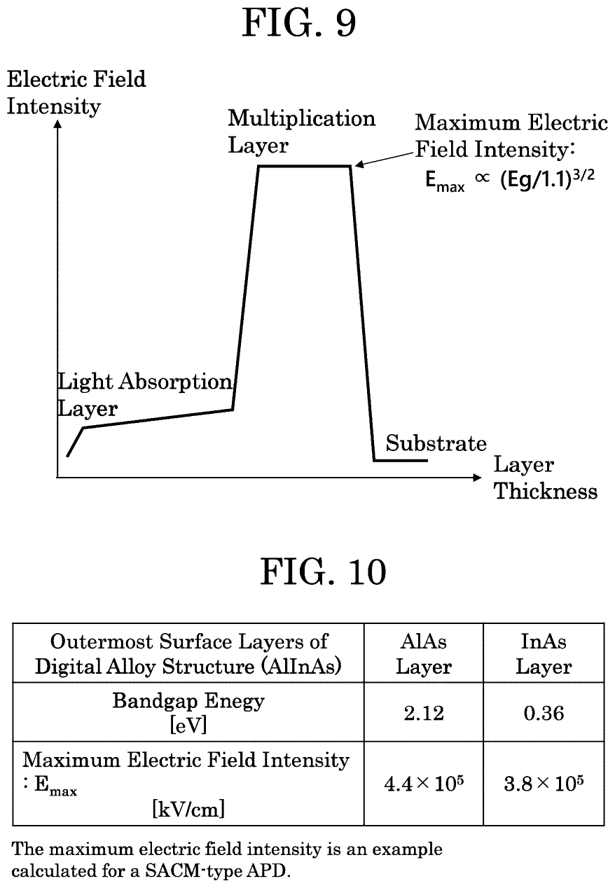

FIG. 9 shows the electric field intensity distribution in the direction perpendicular to the n-type InP substrate 2. In SACM-type APDs, the electric field intensity applied to the i-type AlInAs multiplication layer 4d composed of the digital alloy structure is increased such that the carriers are avalanche-multiplied. In contrast, in order to prevent the carriers from being multiplied in the n-type InGaAs light absorption layer 6, the electric field intensity of the n-type InGaAs light absorption layer 6 is reduced by controlling the electric field intensity using the p-type AlInAs electric field relaxation layer 5. In this case, the maximum electric field intensity Eₘₐₓ of the i-type AlInAs multiplication layer 4d has a relationship expressed by the following Expression (4) with the bandgap energy Eg of the i-type AlInAs multiplication layer 4d composed of the digital alloy structure.

$$[ Mathematical Formula 4 ]$$

$${E}_{max} ∝ {( {E}_{g} / 1.1 )}^{\frac{3}{2}} \qquad ( 4 )$$

The Expression (4) shows that that as the bandgap energy Eg of the i-type AlInAs multiplication layer 4d composed of the digital alloy structure increases, the maximum electric field intensity Eₘₐₓ also increases, and thus, the SACM-type APD can take a larger controllable voltage. For example, in the case where the i-type AlInAs multiplication layer 4d composed of the digital alloy structure is formed of binary compound materials of the InAs layer and the AlAs layer, the AlAs layer having a larger bandgap energy is used as the outermost surface layers of the digital alloy structure, whereby the maximum electric field intensity Eₘₐₓ in the entire device can be increased.

FIG. 10 shows a comparison of the maximum electric field intensity Eₘₐₓ between the case where the outermost surface layers of the i-type AlInAs multiplication layer 4d having the digital alloy structure are the AlAs layers and the case where the outermost surface layers are the InAs layers. As shown in FIG. 10, the maximum electric field intensity Eₘₐₓ is 4.4×10⁵ kV/cm in the case where the outermost surface layers are the AlAs layers, whereas the maximum electric field intensity Eₘₐₓ is 3.8×10⁵ kV/cm in the case where the outermost surface layers are the InAs layers, which means that the outermost surface layers composed of the AlAs layer enable a larger maximum electric field intensity Eₘₐₓ.

In addition, since the semiconductor material having a larger bandgap energy is present on the outermost surfaces of the multiplication layer, even when a local electric field is generated at the interface between the electric field relaxation layer and the multiplication layer, the tolerance to the electric field is increased, and furthermore, the electron barrier ΔEc which interferes with the carrier conduction can be reduced.

In Embodiment 5, the configuration in which the AlAs layers in the i-type AlInAs multiplication layer 4d composed of the digital alloy structure are the outermost surface layers has been described as an example. The same effect can be also achieved when the semiconductor layers with the larger bandgap energy among two kinds of semiconductor layers constituting the multiplication layer composed of the digital alloy structure are set as the outermost surface layers. Furthermore, the same effect can be achieved without limiting the semiconductor material, as long as the bandgap energy is satisfied with a large or small bandgap energy relationship.

The two kinds of semiconductor layers constituting the multiplication layer composed of the digital alloy structure are not limited to the binary compound semiconductor materials as described in the above example, but may be, for example, ternary compound semiconductor materials such as AlₓIn₁₋ₓAs or quaternary compound semiconductor materials such as AlₓGa_{y}In_{1-x-y}As. Furthermore, the multiplication layer may be doped with an impurity so as to have a conductivity type of, for example, a p-type or an n-type, instead of being undoped as shown in the example.

### Effects of Embodiment 5

As described above, according to the semiconductor light-receiving device of Embodiment 5, since the semiconductor layers having a larger bandgap energy of the two kinds of semiconductor layers constituting the multiplication layer composed of the digital alloy structure are set as the outermost surface layers, the maximum electric field intensity in the multiplication layer composed of the digital alloy structure is increased, and thus the control width of the operable voltage can be widened, thus providing an effect of achieving a semiconductor light-receiving device capable of high-speed operation.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 n-type electrode
2 n-type InP substrate
3 n-type AlInAs buffer layer
4 4d i-type AlInAs multiplication layer
4a first semiconductor layer
4b second semiconductor layer
5 p-type AlInAs electric field relaxation layer,
6 n-type InGaAs light absorption layer
7 i-type AlInAs window layer
8 n-type InP window layer
9 p-type InGaAs contact layer
10 Zn selective diffusion region
11 SiNₓ surface protective film
12 p-type electrode
21 i-type AlInAs strain relaxation layer
22 i-type AlxGayInli_x-yAs first transition layer
23 i-type AlxGayInli_x-yAs second transition layer
100, 110, 120, 130, 140 semiconductor light-receiving device

1. A semiconductor light-receiving device comprising:
a semiconductor substrate;
a multiplication layer formed above the semiconductor substrate and configured to amplify photocarriers, the multiplication layer being composed of a digital alloy structure including a first semiconductor layer having a thickness of N times (1≤N≤20) a thickness of a monoatomic layer and a second semiconductor layer having a thickness of M times (1≤M≤20) the thickness of the monoatomic layer with a smaller bandgap energy than the first semiconductor layer, the first semiconductor layer and the second semiconductor layer being alternately stacked a plurality of times in the digital alloy structure;
a light absorption layer formed above the multiplication layer and configured to absorb incident light to generate the photocarriers;
an electric field relaxation layer formed between the multiplication layer and the light absorption layer; and
a strain relaxation layer formed between the multiplication layer and the electric field relaxation layer so as to relax strain of the multiplication layer.

2. The semiconductor light-receiving device according to claim 1, wherein
the thickness of the first semiconductor layer is N times (1≤N≤5) the thickness of the monoatomic layer and the thickness of the second semiconductor layer is M times (1≤M≤5) the thickness of the monoatomic layer.

3. The semiconductor light-receiving device according to claim 1, wherein
the number of times of alternately stacking the first semiconductor layer and the second semiconductor layer is 5 times or more and 300 times or less.

4. The semiconductor light-receiving device according to claim 1, wherein
the first semiconductor layer and the second semiconductor layer are composed of an AlAs layer and an InAs layer, respectively.

5. The semiconductor light-receiving device according to claim 1, wherein
the light absorption layer is made of InGaAs.

6. (canceled)

7. The semiconductor light-receiving device according to claim 1, wherein
the strain relaxation layer is made of a semiconductor material having the same composition as a semiconductor material constituting the multiplication layer.

8. The semiconductor light-receiving device according to claim 1, wherein
the strain relaxation layer is made of AlInAs.

9-12. (canceled)

13. The semiconductor light-receiving device according to claim 1, wherein
a layer of the multiplication layer facing the electric field relaxation layer is the first semiconductor layer.

14. A method for manufacturing a semiconductor light-receiving device, comprising:
a step of sequentially epitaxially growing, above an n-type InP substrate, an n-type AlInAs buffer layer, an AlInAs multiplication layer composed of a digital alloy structure including an AlAs layer having a thickness of N times (1≤N≤20) a thickness of a monoatomic layer and an InAs layer having a thickness of M times (1≤M≤20) the thickness of the monoatomic layer in which the AlAs layer and the InAs layer are alternately stacked a plurality of times, an i-type AlInAs strain relaxation layer, a p-type AlInAs electric field relaxation layer, an n-type InGaAs light absorption layer, an i-type AlInAs window layer, an n-type InP window layer, and a p-type InGaAs contact layer; and
a step of forming a Zn selective diffusion region in the n-type InP window layer and a part of the i-type AlInAs window layer.

15. The method for manufacturing a semiconductor light-receiving device according to claim 14, wherein
the epitaxial crystal growth is performed by an MOVPE method or an MBE method.

16. The method for manufacturing a semiconductor light-receiving device according to claim 14, wherein
the epitaxial crystal growth is performed by an MOVPE method, and a crystal growth temperature is in a range of 500° C. to 600° C.

17. The method for manufacturing a semiconductor light-receiving device according to claim 14, wherein
the thickness of the AlAs layer is N times (1≤N≤5) the thickness of the monoatomic layer, and the thickness of the InAs layer is M times (1≤M≤5) the thickness of the monoatomic layer.

18. The method for manufacturing a semiconductor light-receiving device according to claim 14, wherein
the number of times of alternately stacking the AlAs layer and the InAs layer is 5 times or more and 300 times or less.

19. A semiconductor light-receiving device comprising:
a semiconductor substrate;
a multiplication layer formed above the semiconductor substrate and configured to amplify photocarriers, the multiplication layer being composed of a digital alloy structure including a first semiconductor layer having a thickness of N times (1≤N≤20) a thickness of a monoatomic layer and a second semiconductor layer having a thickness of M times (1≤M≤20) the thickness of the monoatomic layer with a smaller bandgap energy than the first semiconductor layer, the first semiconductor layer and the second semiconductor layer being alternately stacked a plurality of times in the digital alloy structure;
a light absorption layer formed above the multiplication layer and configured to absorb incident light to generate the photocarriers;
an electric field relaxation layer formed between the multiplication layer and the light absorption layer; and
a first transition layer formed between the multiplication layer and the electric field relaxation layer so as to relax strain of the multiplication layer, the first transition layer having a bandgap energy between the bandgap energy of the multiplication layer and the bandgap energy of the electric field relaxation layer.

20. The semiconductor light-receiving device according to claim 19, wherein
the first transition layer is made of AlGaInAs.

21. A semiconductor light-receiving device comprising:
a semiconductor substrate;
a multiplication layer formed above the semiconductor substrate and configured to amplify photocarriers, the multiplication layer being composed of a digital alloy structure including a first semiconductor layer having a thickness of N times (1≤N≤20) a thickness of a monoatomic layer and a second semiconductor layer having a thickness of M times (1≤M≤20) the thickness of the monoatomic layer with a smaller bandgap energy than the first semiconductor layer, the first semiconductor layer and the second semiconductor layer being alternately stacked a plurality of times in the digital alloy structure;
a light absorption layer formed above the multiplication layer and configured to absorb incident light to generate the photocarriers;
an electric field relaxation layer formed between the multiplication layer and the light absorption layer;
a buffer layer formed between the semiconductor substrate and the multiplication layer; and
a second transition layer provided between the multiplication layer and the buffer layer so as to relax strain of the multiplication layer, the second transition layer having a bandgap energy between the bandgap energy of the multiplication layer and the bandgap energy of the buffer layer.

22. The semiconductor light-receiving device according to claim 21, wherein
the second transition layer is made of AlGaInAs.
